(19) United States
(12) Patent Application Publication
(10) Pub. No.: US 2004/0031587 A1
(43) Pub. Date: Feb. 19, 2004

(54) Heat-exchanging fin device fro enhancing heat exchange efficiency

(76) Inventor: Wang Ching Fong, Chang-Hua City (TW)

Correspondence Address: WANG CHING FONG, P.O. BOX 487, Chang-Hua City 500 TW, TW

(21) Appl. No.: 10/388,637

(22) Filed: Mar. 17, 2003

Related U.S. Application Data
(63) Continuation-in-part of application No. 09/995,711, filed on Nov. 29, 2001, now abandoned.

(51) Int. Cl. H05K 7/20

(52) U.S. Cl. 165/80.3; 165/185

(57) ABSTRACT

A heat-exchanging fin device serves for enhancing heat exchange efficiency. The fin device comprises at least two fin plates. Each fin plate comprises a plurality of parallel adjacent straight banks. Each bank has the same width and comprises a plurality of convex portions and concave portions. The concave portions and convex portions are alternatively arranged. Each of the concave portions and convex portions has a U-like shape. Each of the convex portions and concave portions are opened at two ends. In assembly, adjacent banks are shifted with a predetermined length so that the convex portions and concave portions of the adjacent banks are not aligned and thus a portion between two adjacent portions of adjacent banks is opened. Thereby, a plurality of penetrating channels passing through a plurality of banks are formed along the openings of the concave portions and convex portions.

The present invention is a continuation in part of the U.S. patent Ser. No. 09/995,711, which is assigned to the inventor of the present invention, and thus the content of the specification is incorporated into the present invention as a part of this specification.

### BACKGROUND OF THE INVENTION

1. Field of the Invention

The present invention relates to heat dissipating devices, and particularly to a heat-exchanging fin device for enhancing heat exchange efficiency, wherein the fin plates having a plurality of concave portions and convex portions for increasing the turbulent flow of the working fluid (in general, water or air) and thuds the heat dissipating effect is enhanced.

2. Description of Related Art

A prior art heat dissipate structure for increasing heat dissipating effect includes a seat and a heat dissipating portion. The seat is combined above a central processing unit for absorbing heat from the CPU by heat convection so as to avoid the working temperature of the CPU to increase continuously. The feature of the prior art is that a lower end of the seat has an extending seat which is combined with a heat conductive metal piece. The heat dissipating portion includes extending fins at two sides of the seat and a plurality of heat dissipating fins between the two extending fins. The extending fins expand outwards. At least one fin is installed with a wave-like bending section. Air channel is formed between the extending fins and heat dissipating fins. Thereby, heat from CPU can be dissipated from heat conductive metal pieces to the seat. Then it is dispersed from the fins of the heat dissipating portion and the extending fins. As a result, the working temperature of the CPU is retained within a normal range.

Above said heat dissipating seat is approximately identical to that in the prior art. The improvement is that a plurality of fins extends from the seat and expands from the upper portions of two sides. A plurality of wave-like fins are formed between extending fins. The expanding section has spiral grooves for locking fans to an upper end of a heat dissipating seat. However, for heat dissipation, it has only a small increment than that in the prior art. The reason is that the seat and fins are practically heat convection material. Only fans locked above the seat has the function of increasing heat transfer.

The defect of above prior art is that only bottoms of the fins are secured to the seat and the fins are arranged with an equal space. As a result, the fins below the fan has a poor heat dissipating effect, while these fins occupy a large area (referring to FIG. 3 of the prior art). This induces that the CPU is easily overheated. Moreover, since the center of the fan has almost no airflow, heat in that area is guided to the periphery of the fan from other channels. As a result the heat dissipation is not preferred.

### SUMMARY OF THE INVENTION

Accordingly, the primary object of the present invention is to provide a heat-exchanging fin device for enhancing heat exchange efficiency. The fin device comprises at least two fin plates. Each fin plate comprises a plurality of parallel adjacent straight banks. Each bank has the same width and comprises a plurality of convex portions and concave portions. The concave portions and convex portions being alternatively arranged. Each of the concave portions and convex portions having a U-like shape. Bending sections of each of the concave portions and convex portions have a perpendicular bending angle; and each of the con concave portion and convex portions has the same size; each of the convex portions and concave portions are opened at two ends. In assembly, adjacent banks are shifted with a predetermined length so that the convex portions and concave portions of the adjacent banks are not aligned and thus a portion between two adjacent portions of adjacent banks is opened. Thereby, a plurality of penetrating channels passing through a plurality of banks are formed along the openings of the concave portions and convex portions.

The various objects and advantages of the present invention will be more readily understood from the following detailed description when read in conjunction with the appended drawing.

### BRIEF DESCRIPTION OF THE DRAWINGS

FIG. 1 shows a perspective view of an embodiment of the present invention.

FIG. 1A shows a bank in a fin plate according to the present invention.

FIG. 2 shows a longitudinal cross section view of the fin plates of the present invention.

FIG. 3 shows a perspective view of the heat dissipating seat of the present invention, which is formed by a plurality of fin plates.

FIG. 4 shows an elevational view of FIG. 3.

FIG. 5 shows a cross section view of two adjacent fin plates of the present invention.

### DETAILED DESCRIPTION OF THE PREFERRED EMBODIMENTS

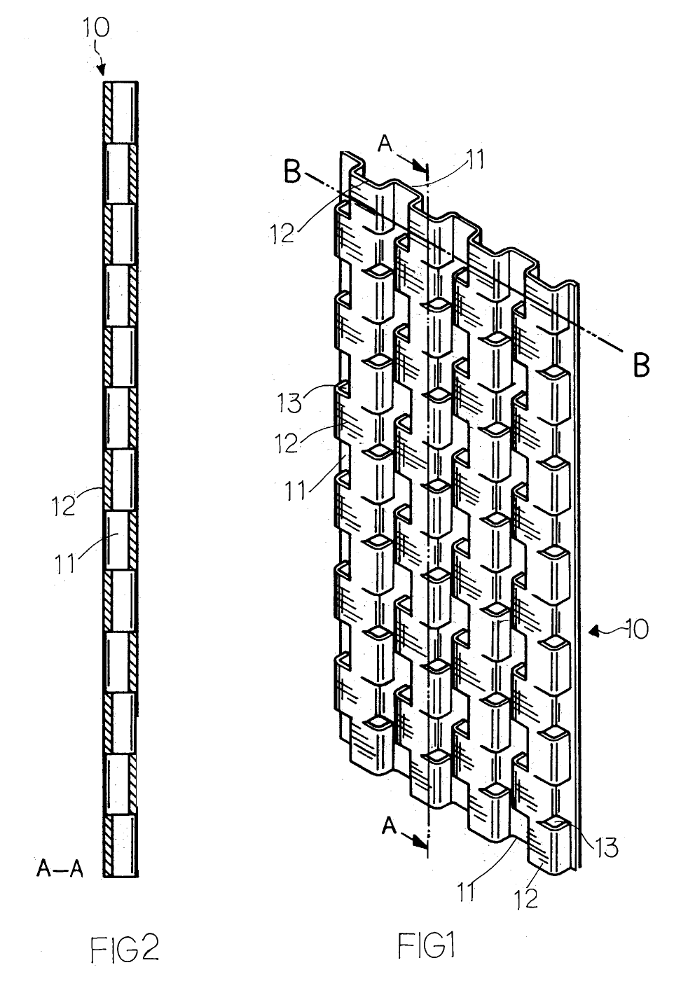

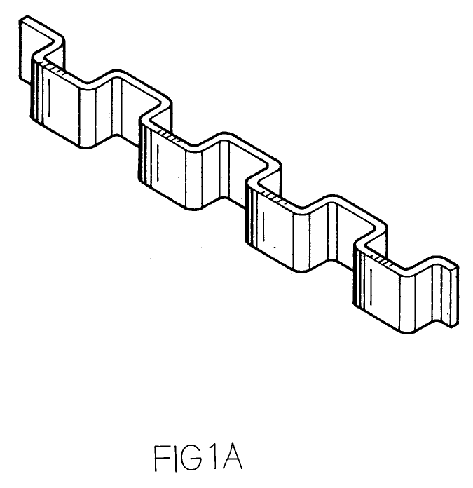

Referring to FIGS. 1 and 2, a heat-exchanging fin device for enhancing heat exchange efficiency, the fin device having at least two fin plates 10 which can be installed to a CPU of a computer or other heat source and then heat is dissipated from a plurality of fin plate so that the CPU or other heat sources can be operated in a normal temperature.

Each fin plate 10 includes a plurality of parallel adjacent straight banks 15 at a direction along line B-B the shown in FIG. 1A. Each bank has the same width and is formed by a plurality of concave portions 11 and convex portions 12. The concave portions and convex portions are alternatively arranged. Each of the concave portions 11 and convex portions 12 has a U-like shape as shown in FIGS. 1 and 1A. The bending sections of each of the concave portions 11 and convex portions 12 have a perpendicular bending angle; and each of the con concave portion and convex portions has the same size. Each of the convex portions and concave portions are opened at two ends not on the surface of the fin plate, as indicated by numeral 16 shown in FIG. 1A.

Adjacent banks 15 are shifted with a predetermined length so that the convex portions 12 and concave portions 11 of the adjacent banks 15 are not aligned and thus a portion between two adjacent portions (convex portions 12 or concave portions 11) of adjacent banks is opened. Thereby, a plurality of penetrating channels (indicated by line A-A in FIG. 1) are formed along the openings of the concave portions and, convex portions; thereby, working fluid flows through the penetrating channels to flow between the fin plates.

In the present invention, the concave portions 12 of the fin plates 10 are connected by sticking, sintering, welding or pressing.

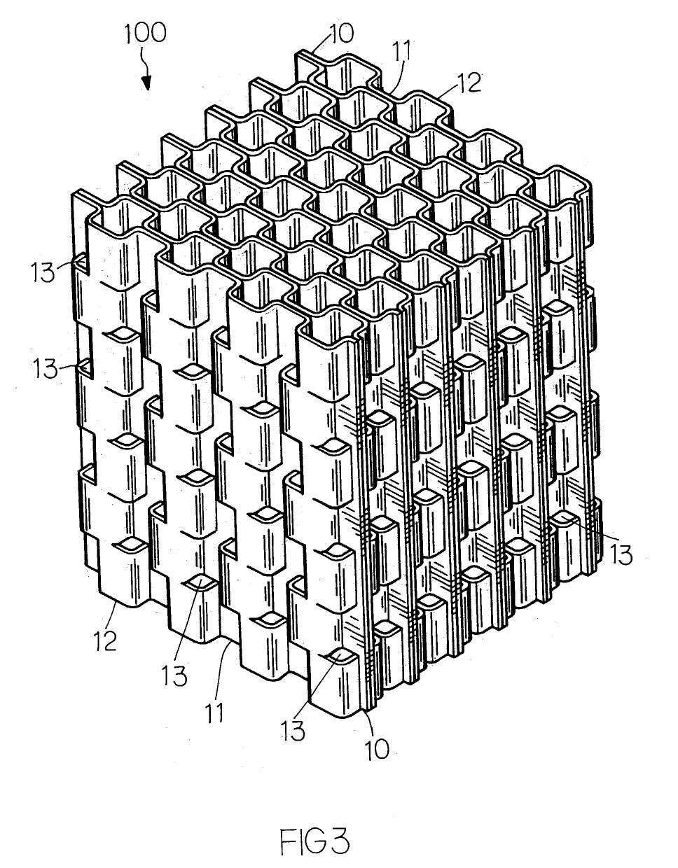

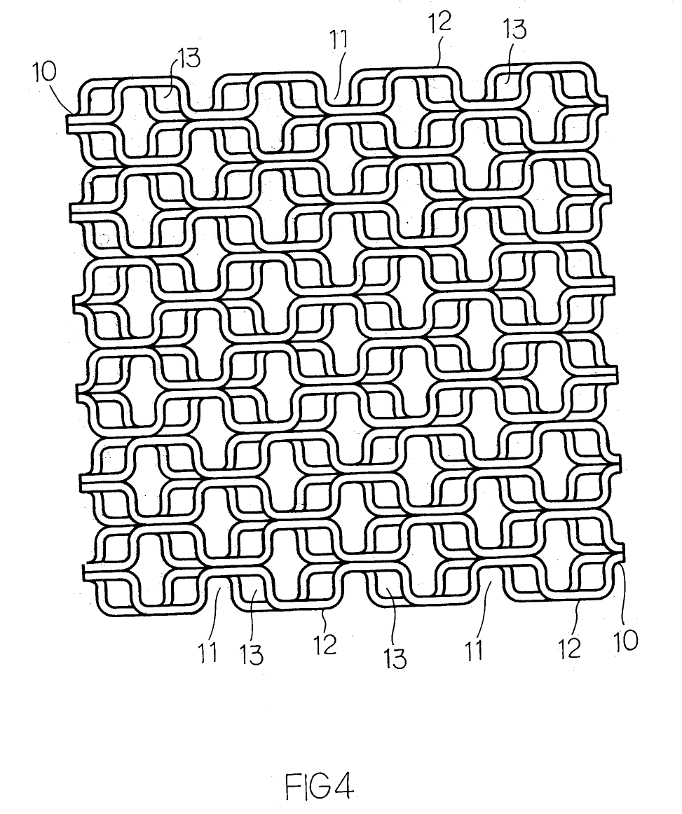

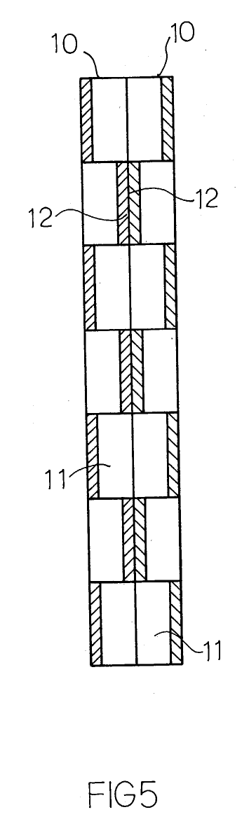

When a plurality of the fin plates are combined, they form a cell-like network (referring to FIGS. 3 and 4). When heat is transferred, the heat is transferred longitudinally or transversally so as to form a three dimensional heat dissipation.

When working fluid flows through the fin plates 10, the concave portions and convex portions are formed as flow resistors, the turbulent flow of the working fluid will enhance, and thus heat convection of the working fluid is increased, thereby,-heat exchange, efficiency is increased.

Moreover, the penetrating channels formed by the openings will interfere the flow dramatically so as to form large vortexes which benefit heat convection of working fluid. Moreover, the working fluids flow into the fin devices from four to five end surfaces. The flow of one heat source may execute a sufficiently heat exchange with flow of other heat source.

In the following, the present invention is compared with fin device formed by a plurality of flat fin plates as those in the prior art. The comparison is based on the two having the same area.

Based on the same area

| Contents | The present invention | Pentium 4 (478 pins) |
|---|---|---|
| Weight | 45 | 45 |
| Number of fins | 84 | 76.7 |
| Effective heat | 244490 mm | 190370 mm |
| dissipating area | | |
| Effective heat | 1566 mm | 1033 mm |
| transferring area | | |
| Vortex | Exist | No |
| Temperature of fin | Small | Large |
| plates | | |
| No. of input planes | Five | Three |

From above comparison, it is apparent that the present invention substantially increases heat dissipating efficiency. Furthermore, heat is transferred along a three dimensional space so that the heat can be dissipated quickly. Moreover, the penetrating channels formed by the openings will interfere the flow dramatically so as to form large vortexes which benefit the heat convection of working fluid.

Furthermore, in the present invention, at least two fin plates are connected through the contacts of the convex portions, and the connecting way is one of buckling connection, welding connection, and sticking connection.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A heat-exchanging fin device for enhancing heat exchange efficiency, the fin device comprising
at least two fin plates; each fin plate comprising:
a plurality of parallel adjacent straight banks; each bank having the same width and comprising
a plurality of convex portions and concave portions; the concave portions and convex portion,'s being alternatively arranged, each of the concave portions and convex portions having a U-like shape; bending sections of each of the concave portions and convex portions have a perpendicular bending angle; and each of the con concave portion and convex portions has the same size; each of the convex portions and concave portions are opened at two ends;
wherein in assembly, adjacent banks are shifted with a predetermined length so that the convex portions and concave portions of the adjacent banks are not aligned and thus a portion between two adjacent portions, i.e., convex portions or concave portions, of adjacent banks is opened; thereby, a plurality of penetrating channels passing through a plurality of banks are formed along the openings of the concave portions and convex portions.

2. The heat-exchanging fin device as claimed in claim 1, wherein a plurality of the fin plates are combined, they form a cell-like network.
